(19) United States
(12) Patent Application Publication
(10) Pub. No.: US 2011/0100606 A1
(43) Pub. Date: May 5, 2011

(54) HEAT DISSIPATING CAVITY

(75) Inventors: JI LI, Beijing (CN); DA-MING WANG, Beijing (CN)

(73) Assignee: Beijing AVC Technology Research Center Co., Ltd., Beijing (CN)

(21) Appl. No.: 12/610,625

(22) Filed: Nov. 2, 2009

(51) Int. Cl. H01L 23/367; F28D 15/04; F28F 7/00; H01L 23/427

(52) U.S. Cl. 165/104.26; 165/185

(57) ABSTRACT

A heat dissipating cavity includes a cavity made of high thermal conductive material having a plurality of heat dissipating fins on the outside thereof, and temperature equalizing elements including heat pipes and heat expansion plates, which can be used individually or collectively. The heat generated by the heating electronic elements inside the cavity is first effectively conducted to the temperature equalizing elements, wherefrom effectively and evenly conducted to the entire cavity, and finally released out of the system by the plurality of heat dissipating fins. The use of temperature equalizing elements increases the homogeneity of the cavity's overall temperature and greatly improves the efficiency of heat dissipation.

### BACKGROUND OF THE INVENTION

1. Field of the Invention

The present invention relates to an electronic heat dissipating apparatus and particularly to an electronic heat dissipating apparatus which employs temperature equalizing elements.

2. Brief Description of Related Art:

Existing cavities are mostly made of metal and manufactured by casting. But due to the limitation of existing casting technology, the material used usually has low thermal conductivity coefficient. The heat generated by electronic parts tends to concentrate in one local area, thereby greatly raising the temperature of that local area and causing the temperature of those electronic parts to exceed their tolerance limit. Yet the remaining big area in the cavity, which is away from those heating electronic parts, is far lower in temperature than the said local area. This results in uneven temperature distribution in the cavity and the exterior fins, and seriously compromises the heat dissipating efficiency of the cavity. To solve the foregoing problem, the existing solution is either to increase the thickness of the cavity or to improve its material. But this kind of solution itself leads to other technical problems, such as the overweight of the cavity.

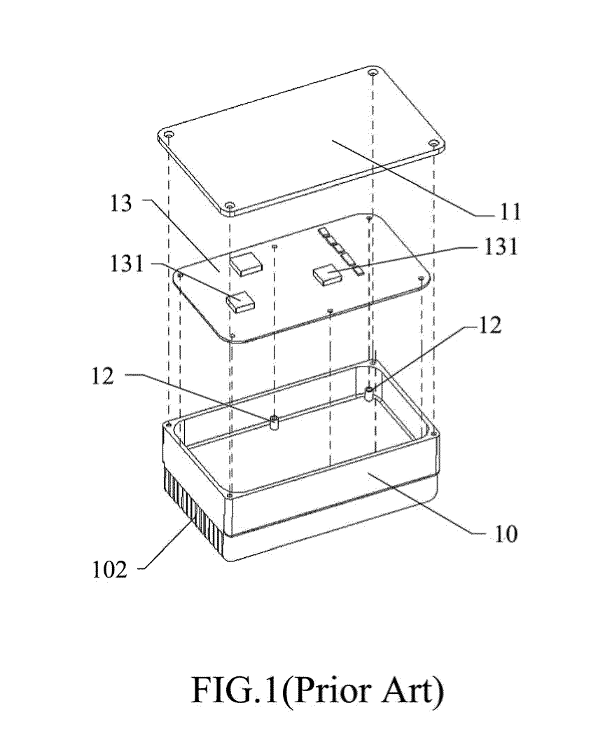

FIG. 1 is an exploded perspective view of a heat dissipating cavity manufactured by existing technology. Referring to FIG. 1, an existing heat dissipating cavity includes a cavity 10, a cover 11, fixed support elements 12, and an electronic board 13. On the exterior surface of the cavity 10 is disposed a plurality of heat dissipating fins 102. Fixed support elements 12 are disposed inside the cavity in accordance with the positioning of the holes and the height of the chips on the electronic board. The function of the cover 11 is to form a closed space, which protects the electronic board from wind, rain, sand, and dust, and which also helps to dissipate heat.

When the electronic board 13 performs, its heating elements 131 (such as CPU, high-power photoelectric parts, radio-frequency electronic parts, or other transistors) will generate a huge amount of heat during calculation. The heat is first conducted to the cavity through the base of the cavity, which is directly in contact with the heating elements, and then released out of the system through the heat dissipating fins. Owing to the limitation of existing manufacturing technology, the material of known cavities has low thermal conductivity coefficient, causing a large amount of heat to concentrate in the small local area where the heat dissipating cavity 10 touches the heating elements 131. The temperature of this small local area is likely to exceed the maximum working temperature limit of the electronic heating elements 131, whereas the remaining big area of the cavity and the heat dissipating fins are too low in temperature to effectively dissipate heat. The effective utilization rate of the fins is therefore rather low. Meanwhile, because the material of the heat dissipating cavity 10 does not effectively accumulate heat, when the heating power of the electronic parts suddenly changes, the amount of accumulated heat will suddenly rise, and the temperature of the electronic heating elements will suddenly rocket, which may damage the electronic parts.

In view of the foregoing considerations, an existing heat dissipating cavity has the following disadvantages:
1. The distribution of temperature in the cavity and the heat dissipating fins is rather uneven, so the cavity's efficiency in dissipating heat is low.
2. When the heating power of the electronic parts suddenly changes, the cavity's thermal response time is longer, which may damage the chips.

In view of the foregoing considerations, the present invention attempts to solve the foregoing problems and improve the foregoing disadvantages.

### SUMMARY OF THE INVENTION

It is an object of this present invention to provide a heat dissipating cavity which can dissipate heat more efficiently.

It is a further object of the present invention to provide a heat dissipating cavity which is lighter in weight.

It is a further object of the present invention to provide a heat dissipating cavity which has a faster thermal response time.

With the above objects in mind, the present invention is a heat dissipating cavity which includes a cavity and temperature equalizing elements. The cavity is made of high thermal conductive material, and a plurality of heat dissipating fins is disposed on the outside thereof. The temperature equalizing elements include heat pipes and heat expansion plates, which can be used individually or collectively, and they are disposed in accordance with the positioning of the heating elements. The heat generated by the heating elements inside the cavity is first effectively conducted to the temperature equalizing elements, wherefrom effectively and evenly conducted to the entire cavity, and finally released out of the system by the plurality of heat dissipating fins. The use of temperature equalizing elements increases the homogeneity of the cavity's overall temperature and greatly improves the efficiency of heat dissipation.

### BRIEF DESCRIPTION OF THE INVENTION

FIG. 1 is an exploded perspective view of an existing heat dissipating cavity.

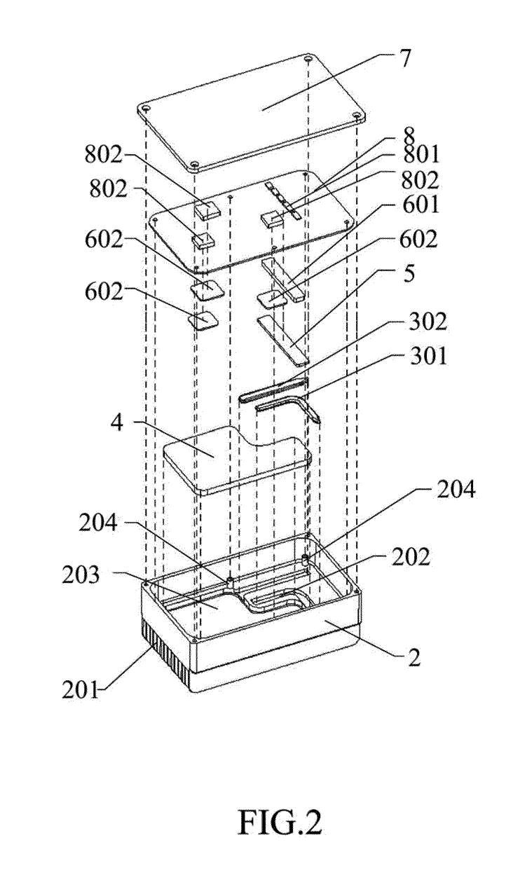

FIG. 2 is an exploded perspective view of a new heat dissipating cavity according to the preferred embodiment of the present invention.

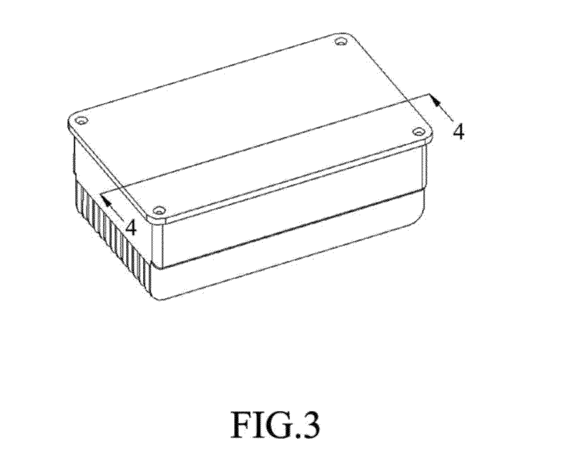

FIG. 3 is an assembled perspective view of the preferred embodiment of the present invention.

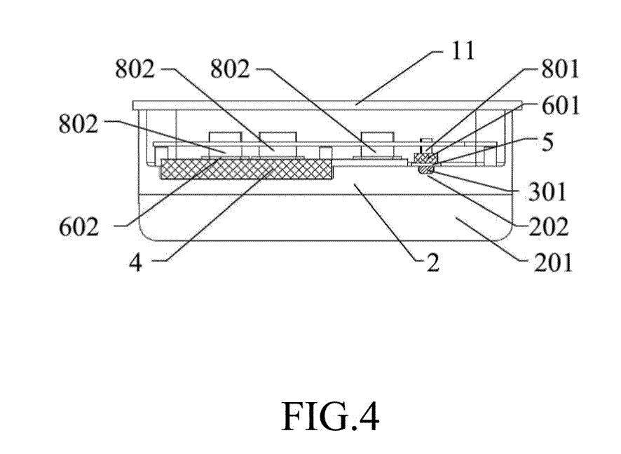

FIG. 4 is a side view of the preferred embodiment of the present invention.

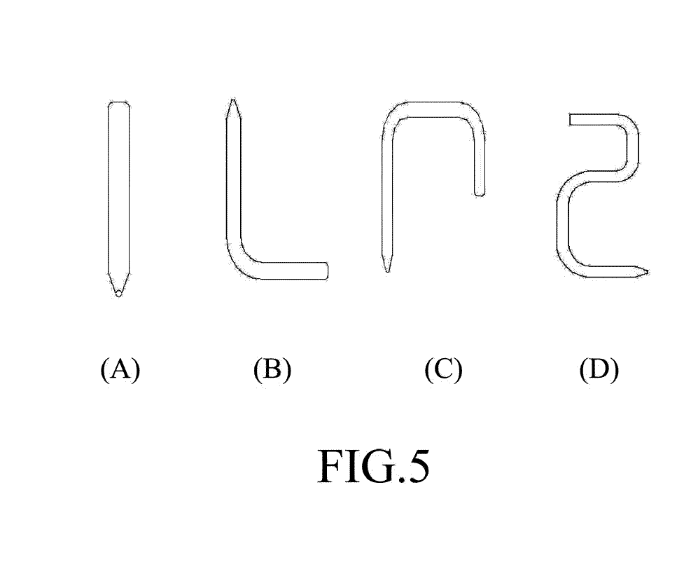

FIG. 5 illustrates the shapes of the heat pipes defined in the present invention.

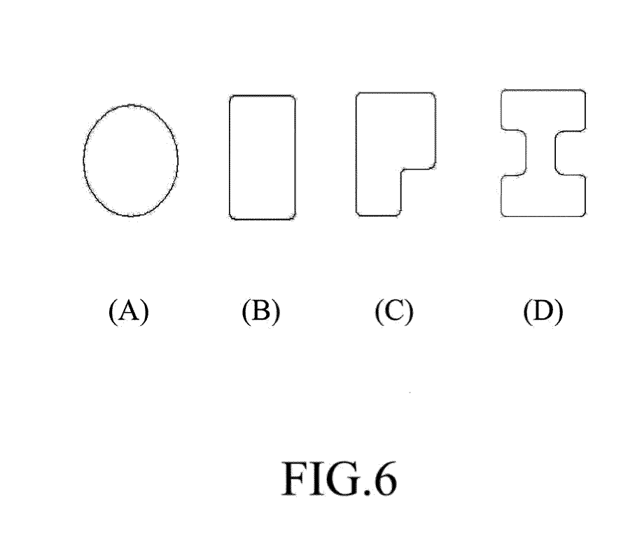

FIG. 6 illustrates the shapes of the heat expansion plates defined in the present invention.

### DETAILED DESCRIPTION OF THE PREFERRED EMBODIMENT

Several aspects of the invention are hereinafter described in detail with reference to FIGS. 2 to 4.

Referring to FIG. 2, the present invention is a heat dissipating cavity. The preferred embodiment includes a cavity 2, temperature equalizing elements (an L-shape heat pipe 301, a straight heat pipe 302, and a heat expansion plate 4 are employed in the preferred embodiment), a copper plate 5, high thermal conductive pads 601 and 602, and a cover 7. On the outside of the cavity is disposed a plurality of heat dissipating fins 201. On the inner base of the cavity 2 are disposed a heat pipe groove 202 and a heat expansion plate groove 203. The cavity 2 of the present invention is designed for the electronic board 8, whereon are disposed heating elements 801 and 802.

In the preferred embodiment of the invention, the L-shape heat pipe 301 and the straight heat pipe 302 can be adhered to the copper plate 5 by welding, heat conductive glue, or screws before being disposed in the heat pipe groove 202 in the same manner. The heat generated by the heating elements 801 is conducted through the high thermal conductive pad 601, the copper plate 5, the L-shape heat pipe 301, and the straight heat pipe 302 to the cavity 2, and then released out of the system by the heat dissipating fins 201. The heat expansion plate 4 can also be disposed in the heat expansion plate groove 203 by welding, heat conductive glue, or screws. The heat generated by the heating elements 802 is conducted through the high thermal conductive pads 602 and the heat expansion plate 4 to the cavity 2, and then released out of the system by the heat dissipating fins 201. The use of the L-shape heat pipe 301, the straight heat pipe 302, the heat expansion plate 4, the copper plate 5, and the high thermal conductive pads 6 facilitates even temperature increase across the entire cavity and raises the effective utilization rate of the heat dissipating fins 201, thereby achieving better heat dissipation. With the use of lighter materials for the L-shape heat pipe 301, the straight heat pipe 302, and the heat expansion plate 4, and a thinner base for the cavity 2, the cavity 2 of the present invention is much lighter in weight in comparison with any existing cavity.

The application of the present invention is hereinafter described in detail with reference to FIGS. 2 to 6.

The cavity 2 can be made of high thermal conductive materials such as aluminium or other compound metals. On the inner base of the cavity are disposed a heat pipe groove 202 and a heat expansion plate groove 203, whereto an L-shape heat pipe 301, a straight heat pipe 302, a heat expansion plate 4, and a copper plate 5 can be adhered by welding. To meet the requirements of welding, both the inner and outer surfaces of the cavity 2 are thoroughly or partially treated with chemical nickel plating, which can also meet the anti-corrosion requirements of the surfaces. Corresponding treatment of the surface has to be done if the L-shape heat pipe 301, the straight heat pipe 302, the heat expansion plate 4, and the copper plate 5 are adhered to the cavity by thermal conductive glue or screws.

The inner base of the cavity, whereto the foregoing L-shape heat pipe 301, the straight heat pipe 302, and the heat expansion plate 4 are adhered, can be in various forms, including but not limited to the groove or powder structure. The number and shape of the heat pipes and the heat expansion plates are determined by the heating power of the heating elements 801 and 802 on the electronic board 8, their maximum working temperature limit, and their structure. In the preferred embodiment of the present invention, one L-shape heat pipe 301 and one straight heat pipe 302 are disposed. The shape of the heat pipes include but are not limited to the shapes shown in FIG. 5. The respective heat pipes can be “Straight” as shown in FIG. 5(A), “L” shaped as shown in FIG. 5(B), “N” shaped as shown in FIG. 5(C), or “S” shaped as shown in FIG. 5(D). The shape of the heat expansion plates include but are not limited to the shapes shown in FIG. 6. The respective heat expansion plates can be oval as shown in FIG. 6 (A), rectangular as shown in FIG. 6 (B), or irregular as shown in FIG. 6(C) and FIG. 6 (D).

The shape of the copper plate 5 is determined by the shape of the heating elements 801; it should completely cover the surface of the heating elements, so that it can smoothly and completely touches the surface of the heat source. Because copper has high thermal accumulation coefficient and thermal conductivity coefficient, the thermal response time of the heat dissipating cavity is short when the heating power of the heating elements 801 suddenly rises. The material of this element includes but is not limited to such high thermal conductive materials as copper, aluminium, and graphite.

The high thermal conductive pad 601 of the heat pipe is as big as or slightly bigger than the copper plate. Its function is to make the contact between the copper plate 5 and the heating element 801 elastic, efficiently reducing the thermal contact resistance and the requirements of manufacturing precision. It is within the scope of the present invention to replace these elements by the thermal conductive paste which is applied to the surface of the copper plate.

The function of the cover 7 is to form a closed space, which protects the electronic board from wind, rain, sand, and dust, and which also helps to dissipate heat. In the present invention, in order to improve its efficiency in dissipating heat, the cover 7 can be treated in the same way as the cavity 2. Grooves can be disposed on the side of the cover facing the electronic board 8 to hold heat pipes and heat expansion plates, and auxiliary heat dissipating structures such as heat dissipating fins can be disposed on the other side thereof. All the foregoing changes and modifications are within the scope of the present invention.

The electronic board 8 is screwed onto the fixed support elements 204 and adhered to the inner base of the cavity 2.

In view of the foregoing considerations, the present invention is a new heat dissipating cavity which has the following advantages:

1. It is more efficient in heat dissipation.

2. It is lighter in weight.

3. It has a faster thermal response time.

It is to be understood that the form of our invention herein shown and described is to be taken as a preferred example of the same and that various changes in the method, shape, structure, and installation may be resorted to without departing from the spirit of our invention on the scope of the subjoined claims.

What is claimed is:

1. A heat dissipating cavity comprising:
a cavity having a plurality of heat dissipating fins disposed on its exterior surface and a base in its inner surface; and
temperature equalizing elements disposed on the inner base of the cavity, which effectively and evenly conduct the heat generated by heating electronic parts to the entire cavity and then release it out of the system through heat dissipating fins.

2. The heat dissipating cavity of claim 1 wherein grooves, positioning holes, and other structures are disposed on the inner base of the cavity to hold temperature equalizing elements.

3. The heat dissipating cavity of claim 1 wherein the temperature equalizing elements include heat pipes and heat expansion plates, which are used individually or collectively.

4. The heat dissipating cavity of claim 1 wherein the inner structure of the cavity base includes but is not limited to the groove or powder structure.
